(19) United States
(12) Patent Application Publication
(10) Pub. No.: US 2020/0306755 A1
(43) Pub. Date: Oct. 1, 2020

(54) MICROFLUIDIC CHIP AND MICROSCOPIC IMAGE SYSTEM

(71) Applicant: NATIONAL CHENG KUNG UNIVERSITY, Tainan City (TW)

(72) Inventors: Hsien-Chang Chang, Tainan City (TW); Wen-Chien Ko, Tainan City (TW); Po-Lin Chen, Tainan City (TW); Chung-Hsin Shih, Taipei City (TW)

(21) Appl. No.: 16/769,332

(22) PCT Filed: Dec. 11, 2018
(86) PCT No.: PCT/IB2018/059851

§ 371 Date: Jun. 3, 2020

Related U.S. Application Data
(60) Provisional application No. 62/597,899, filed on Dec. 12, 2017.

(30) Foreign Application Priority Data
Nov. 2, 2018 (TW) 107139015

(51) Int. Cl. B01L 3/00; B81B 1/00; G02B 21/24; G02B 21/06; G02B 21/34; G01N 1/40; G01N 21/64

(52) U.S. Cl. CPC B01L 3/502715; B01L 2300/165; G02B 21/241; G02B 21/06; G02B 21/34; G01N 1/4077; G01N 21/6452; B81B 2203/0338; B81B 2201/057; B01L 2300/0819; B01L 2300/047; B01L 2300/06; B01L 2300/041; B01L 2300/048; B01L 2300/12; B81B 1/006

(57) ABSTRACT

A microfluidic chip includes a chip main body having a rotation center, a sample reservoir, a liquid groove, multiple reaction chambers, a first inlet channel and multiple second inlet channels, and a sealing membrane connected to the chip main body. The liquid groove has a feeding groove portion extending around the rotation center and the sample reservoir, and multiple metering groove portions extending away from the rotation center. The first inlet channel communicates the sample reservoir and the feeding groove portion. Each second inlet channel communicates a respective metering groove portion and a respective reaction chamber. The depth of the first inlet channel is smaller than those of the sample reservoir and the feeding groove portion. The depth of each second inlet channel is smaller than those of the respective metering groove portion, the respective reaction chamber and the first inlet channel.

### FIELD

The disclosure relates to a fluid chip and an image system, and more particularly to a microfluidic chip and a micro-image system.

### BACKGROUND

Biological and chemical test methods, such as antimicrobial susceptibility testing (AST), nucleic acid detection, biochemical reaction test, enzyme-linked immunosorbent assay (ELISA), protein-protein interaction test, pesticide testing, etc. often entail a great deal of manual operation. When there are multiple test samples, loading the test samples and reagents one at a time using mechanical pipettes becomes time-consuming.

96-well plates, with the use of multichannel pipettes, are currently standardized test platform widely used in many small and medium-sized laboratories. Despite the advantage of human multitasking with the use of multichannel pipettes, performing the conventional testing method with multiple steps becomes extremely erroneous due to lack of attention to each of the pipetting steps. As such, mistakes due to the possible human error may lead to inaccurate testing results. On the other hand, automated pipettes are used for loading test samples in medium and large-sized laboratories. Although the automated pipettes can alleviate the issues associated with manual operation, the automated machine is large-sized, expensive and difficult to maintain.

Microfluidics chips are recently developed solution to fluid dispensing. With tailor-made microstructure and process, the liquid manipulation process can be simplified and the amount of reagents needed can be reduced. Moreover, the microfluidics chips can be applied to laboratories of any size and variety of applications, such as those previously mentioned. Although the current lab-on-a-disk design can meet most testing requirements, it is still desirable to improve different aspects of testing, such as rapid and precise loading of test samples with the right quantity, concurrently handling of multiple test conditions, prevention of interference among distinct tests, even uniformly distribution of liquid, and improve reproducibility.

Conventional micro-image system requires repetitive and time-consuming manual operation by a technician, whose human factors such as fatigue and inconsistent operation procedures may affect precision of the image retrieved. While XY table used with the conventional micro-image system may solve the foregoing problems, the XY table may possess precision issue and cannot be easily calibrated. An automated micro-image system, while more precise, is large in size, complicated to manipulate and expensive to maintain. In addition, differences in ambient light may contribute to the inconsistency of the illumination intensity, causing scanning of multiple images to be less comparable.

### SUMMARY

Therefore, an object of the disclosure is to provide a microfluidic chip and a microscopic image system that can alleviate at least one of the drawbacks of the prior art.

According to a first aspect of the present disclosure, a microfluidic chip includes a chip main body and a sealing membrane.

The chip main body has a rotation center, a sample reservoir, a liquid groove, a plurality of reaction chambers, a first inlet channel and a plurality of second inlet channels. The liquid groove has a feeding groove portion that extends around the rotation center and the sample reservoir. The metering groove portions are disposed around the feeding groove portion, extend from the feeding groove portion in a direction away from the rotation center, and are spaced apart from each other along the length of the feeding groove portion. The reaction chambers are disposed around the metering groove portions. The first inlet channel is in fluid communication with and disposed between the sample reservoir and the feeding groove portion. Each of the second inlet channels is in fluid communication with and disposed between a respective one of the metering groove portions and a respective one of the reaction chambers. The sealing membrane is connected to the chip main body, covers the sample reservoir, the liquid groove, the reaction chambers, the first inlet channel and the second inlet channels so as to seal top ends thereof, and has a sample injection hole that is formed therethrough and that is in fluid communication with the sample reservoir.

The depth of the first inlet channel is smaller than those of the sample reservoir and the feeding groove portion.

The depth of each of the second inlet channels is smaller than the depth of the respective metering groove portion, the depth of the respective reaction chamber, and the depth of the first inlet channel.

According to a second aspect of the present disclosure, a microscopic image system includes a machine case assembly, an image capture device and a holding platform assembly.

The machine case assembly includes a machine case, and a light source unit that is mounted to the machine case and that is operable to emit light downwardly. The image capture device is mounted to the machine case, and includes a focus adjusting module and a microscopic image module that is mounted to the focus adjusting module. The microscopic image module is drivable by the focus adjusting module to move vertically. The microscopic image module includes an objective lens that is within the lighting area of the light source unit and that is adapted to capture image, a lens barrel that extends vertically and that is connected to a lower end of the objective lens and a photodetector that is connected to a lower end of the lens barrel and that is adapted for capturing images through the objective lens. The holding platform assembly includes a driving unit that is mounted to the machine case, and a holding platform that is mounted to the driving unit and that is disposed above the objective lens. The holding platform has a plurality of inspection through holes formed therethrough and are drivable by the driving unit to move horizontally such that a selected one of the inspection through holes is located above the objective lens.

### BRIEF DESCRIPTION OF THE DRAWINGS

Other features and advantages of the disclosure will become apparent in the following detailed description of the embodiment and variation with reference to the accompanying drawings, of which:

FIG. 1 is a schematic perspective view of an embodiment of a microscopic image system according to the present disclosure and a microfluidic chip used therewith;

FIG. 2 is a perspective view of the microfluidic chip;

FIG. 3 is a top view of the microfluidic chip;

FIG. 4 is a sectional view of the microfluidic chip, taken along line A-A of FIG. 3;

FIG. 5 is a sectional view of the microfluidic chip, taken along line B-B of FIG. 3;

FIGS. 6 to 8 are consecutive top views showing test solution being distributed in the microfluidic chip;

FIG. 9 is a schematic perspective view of the embodiment, showing a cover of the embodiment covering a top end of a machine case of the same;

FIG. 10 is a sectional view of the embodiment;

FIG. 11 is a block diagram illustrating the connection of different elements of a microscopic image system of the embodiment;

FIG. 12 is a sectional view of a variation of the embodiment;

FIG. 13 is an exploded perspective view of a variation of the microfluidic chip; and

FIG. 14 is a sectional view of the variation of the microfluidic chip.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

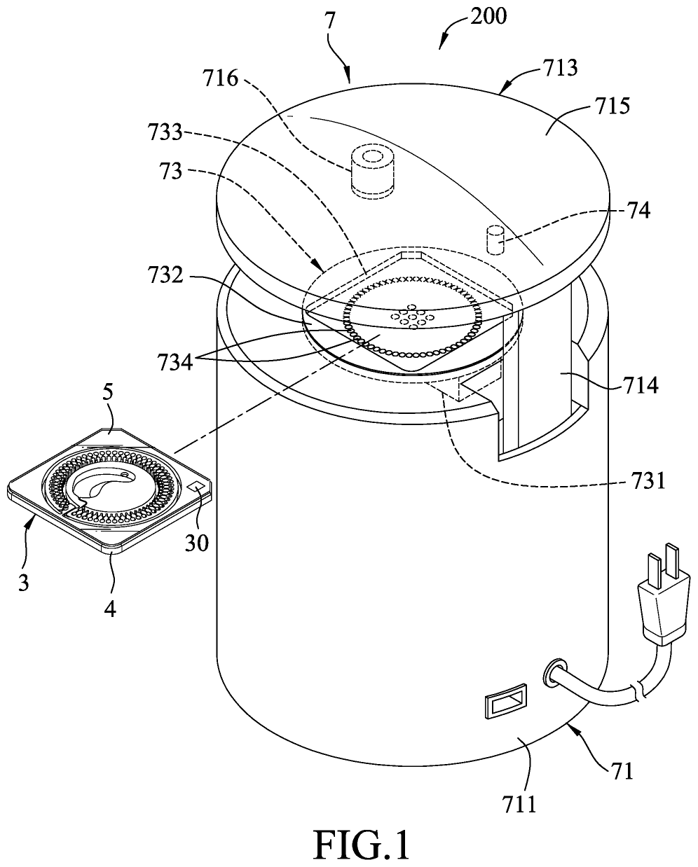

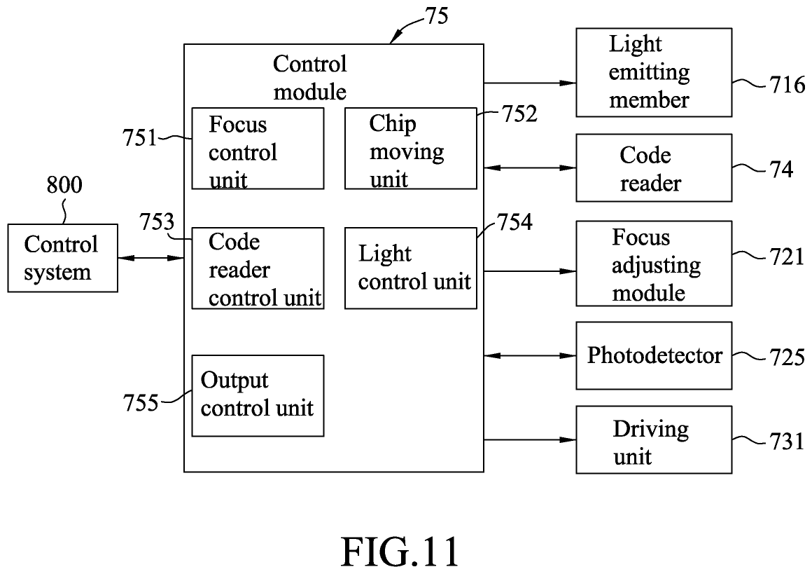

Referring to FIGS. 1 and 11, an embodiment of a microscopic image system 7 is shown. A microfluidic chip 3 is used with the microscopic image system 7 to cooperatively serve as a microfluidic chip image system 200 for testing samples loaded to the microfluidic chip and capturing images of the samples using the microscopic image system 7. The microfluidic chip image system 200 may be in signal connection to a control system 800, such as computers or cell phones, for an operator to control the microfluidic chip image system 200.

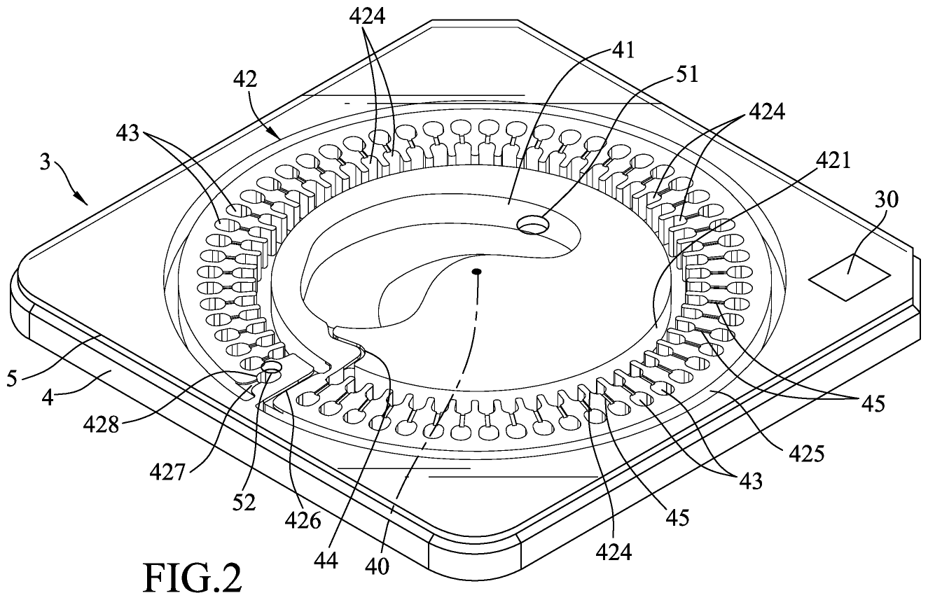

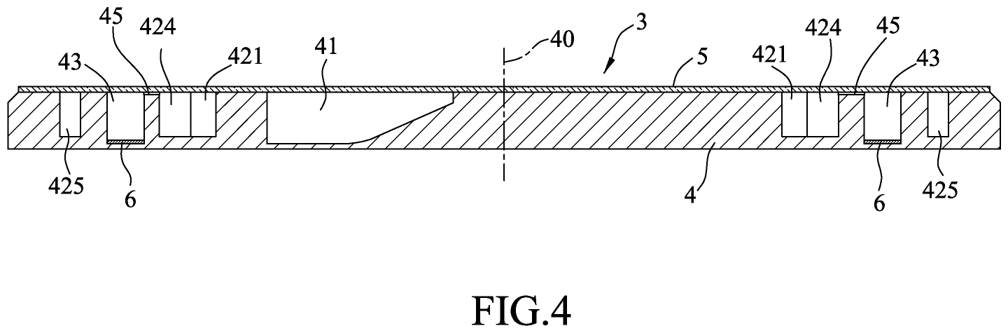

Referring to FIGS. 2, 3 and 4, the microfluidic chip 3 allows quantitative addition of sample solution to reaction chambers thereof. The sample solution may contain blood, urine, microorganisms, cells, nucleic acids, antibodies or other biological or chemical substances to be tested.

The microfluidic chip 3 includes a plate-shaped chip main body 4, a sealing membrane 5 connected thereto to seal a top surface of the chip main body 4, and a plurality of reagents 6 disposed on the chip main body 4 and covered by the sealing membrane 5. The chip main body 4 may be made of a transparent or opaque hydrophobic material, such as poly(methyl methacrylate) (PMMA), cyclic olefin copolymer (COP), polycarbonate (PC), polyamide (PA), polypropylene (PP), etc. In this embodiment, the chip main body 4 has a vertical rotation center 40 and an identification code 30 disposed on a top surface thereof. The chip main body 4 further has a sample reservoir 41, a liquid groove 42, a plurality of reaction chambers 43, a first inlet channel 44 and a plurality of second inlet channels 45.

The sample reservoir 41 extends around the rotation center 40, and has a first end 411 and a second end 412 that are respectively located at two sides of the rotation center 40. The distance between the second end 412 of the sample reservoir 41 and the rotation center 40 is greater than the distance between the first end 411 of the sample reservoir 41 and the rotation center 40. The depth of the sample reservoir 41 increases in a direction away from the rotation center 40 and increases from the first end 411 of the sample reservoir 41 toward the second end 412 of the sample reservoir 41.

The liquid groove 42 has a feeding groove portion 421, a plurality of metering groove portions 424, a liquid storage groove portion 425, a connecting groove portion 426, a venting channel 427 and a venting groove portion 428.

The feeding groove portion 421 extends around the rotation center 40 and the sample reservoir 41, and has a first feeding end 422 and a second feeding end 423 opposite to the first feeding end 422. In this embodiment, the feeding groove portion 421 extends gradually away from the rotation center 40 from the first feeding end 422 to the second feeding end 423.

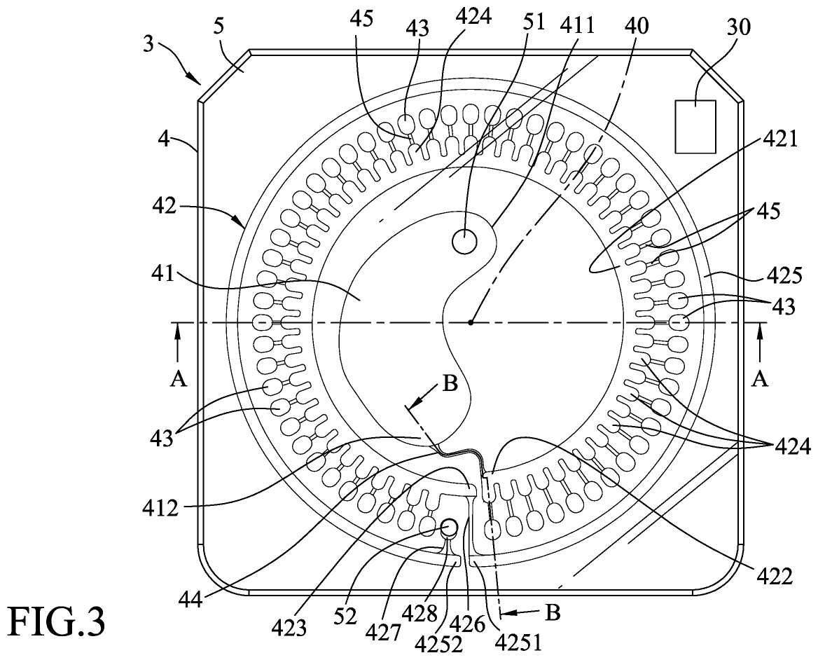

Specifically, the feeding groove portion 421 extends counterclockwisely (as seen from the top view of FIG. 3) along a path shaped as an involute of a circle such that the distance between the second feeding end 423 and the rotation center 40 is greater than the distance between the first feeding end 422 and the rotation center 40.

Referring to FIGS. 2, 3 and 5, the first inlet channel 44 is in fluid communication with and disposed between the second end 412 of the sample reservoir 41 and the first feeding end 422 of the feeding groove portion 421.

The metering groove portions 424 are disposed around the feeding groove portion 421, extend from the feeding groove portion 421 in a direction away from the rotation center 40, and are spaced apart from each other along the length of the feeding groove portion 421. In this embodiment, the metering groove portions 424 surround the feeding groove portion 421.

The reaction chambers 43 are disposed around the metering groove portions 424. In this embodiment, the reaction chambers 43 surround the metering groove portions 424.

Each of the second inlet channels 45 is in fluid communication with and disposed between a respective one of the metering groove portions 424 and a respective one of the reaction chambers 43. In this embodiment, each of the second inlet channels 45 extends from the respective metering groove portion 424 to the respective reaction chamber 43 in a manner that the extension length thereof decreases from one corresponding to the first feeding end 422 of the feeding groove portion 421 toward one corresponding to the second feeding end 423 of the feeding groove portion 421.

The liquid storage groove portion 425 extends around the feeding groove portion 421, and has a first end 4251 and a second end 4252 opposite to the first end 4251. In this embodiment, the liquid storage groove portion 425 extends along a circle and surrounds the reaction chambers 43 such that the first and second ends 4251, 4252 are adjacent to each other.

The connecting groove portion 426 is in fluid communication with and disposed between the second feeding end 423 of the feeding groove portion 421 and the first end 4251 of the liquid storage groove portion 425, and extends radially and outwardly from the second feeding end 423 of the feeding groove portion 421 relative to the rotation center 40.

The venting channel 427 extends from the second end 4252 of the liquid storage groove portion 425 toward the rotation center 40. The venting groove portion 428 is disposed between the liquid storage groove portion 425 and the feeding groove portion 421, and communicates with an end of the venting channel 427 distal from the liquid storage groove portion 425.

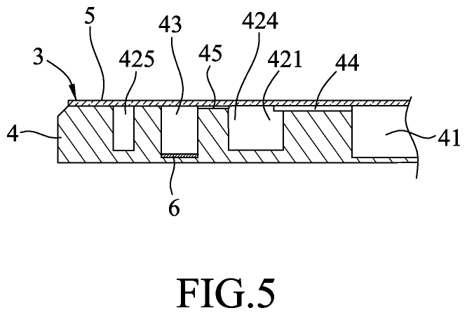

Referring further to FIG. 5, the depth of the first inlet channel 44 is smaller than those of the sample reservoir 41 and the feeding groove portion 421. The depth of each of the second inlet channels 45 is smaller than the depth of the respective metering groove portion 424, the depth of the respective reaction chamber 43 and the depth of the first inlet channel 44. Referring back to FIGS. 2 and 3, the depth of the connecting groove portion 426 is smaller than those of the feeding groove portion 421 and the liquid storage groove portion 425, and the depth of the venting channel 427 is smaller than those of the liquid storage groove portion 425 and the venting groove portion 428.

In certain embodiments, the depths of the sample reservoir 41, the feeding groove portion 421, the metering groove portions 424, the reaction chambers 43, the liquid storage groove portion 425 and the venting groove portion 428 range from 3 mm to 6 mm. In this embodiment, the depths of the sample reservoir 41, the reaction chambers 43, the liquid storage groove portion 425 and the venting groove portion 428 are 5 mm, and the depths of the feeding groove portion 421 and the metering groove portions 424 are 4.3 mm. The volume of each of the metering groove portions 424 is smaller or equal to that of the respective reaction chamber 43. In this embodiment, the volume of each of the metering groove portions 424 is 30 μL, and the volume of the respective reaction chamber 43 is 40 μL. The width of the first inlet channel 44 may range from 0.6 mm to 1 mm, and the depth of the first inlet channel 44 may range from 0.4 mm to 0.5 mm. In this embodiment, the width of the first inlet channel 44 is 1 mm, and the depth of the first inlet channel 44 is 0.5 mm. The width of each of the second inlet channels 45 may range from 0.6 mm to 1 mm, and the depth of each of the second inlet channels 45 may range from 0.1 mm to 0.35 mm. In this embodiment, the width of each of the second inlet channels 45 is 1 mm, and the depth of each of the second inlet channels 45 is 0.25 mm. In this embodiment, the depth of the venting channel 427 equals to those of the connecting groove portion 426 and the first inlet channel 44.

The sealing membrane 5 may be made of a hydrophobic material, such as polyethylene (PE), polypropylene (PP), polyurethane (PU), thermoplastic polyurethane (TPU), biaxially oriented polypropylene (BOPP), and may be made by an airtight membrane or a waterproof-breathable membrane. The sealing membrane 5 covers the sample reservoir 41, the liquid groove 42, the reaction chambers 43, the first inlet channel 44 and the second inlet channels 45 so as to seal top ends thereof. The sealing membrane 5 has a sample injection hole 51 that is formed therethrough and that communicates with the first end 411 of the sample reservoir 41, and a venting hole 52 that communicates with the venting groove portion 428.

The reagents 6 are respectively fixed to sides of the reaction chambers 43, such as bottom sides or side walls. The reagents 6 are formed by coating and drying reacting reagents on the sides, and dissolve in and react with the sample solution. The reagents 6 may be antibiotics, antibodies for immunosorbent reaction, probes for detecting genetic materials (e.g., DNA) or other substances that are capable of reacting with the sample solution.

In operation, the reacting solution is injected into the sample reservoir 41 of the microfluidic chip 3 through the sample injection hole 51 of the sealing membrane 5. Thereafter, the microfluidic chip 3 is loaded to a centrifuge (not shown in the figure), and the microfluidic chip 3 is rotated about the rotation center 40 thereof such that the centrifugal force generated by the rotation distributes the reacting solution in the microfluidic chip 3. With the various depth structure of the first inlet channel 44 and the second inlet channels 45, different rotation speeds of the centrifuge can be used for sequentially distributing the reacting solution from the sample reservoir 41 to the feeding groove portion 421 and from the metering groove portions 424 to the reaction chambers 43.

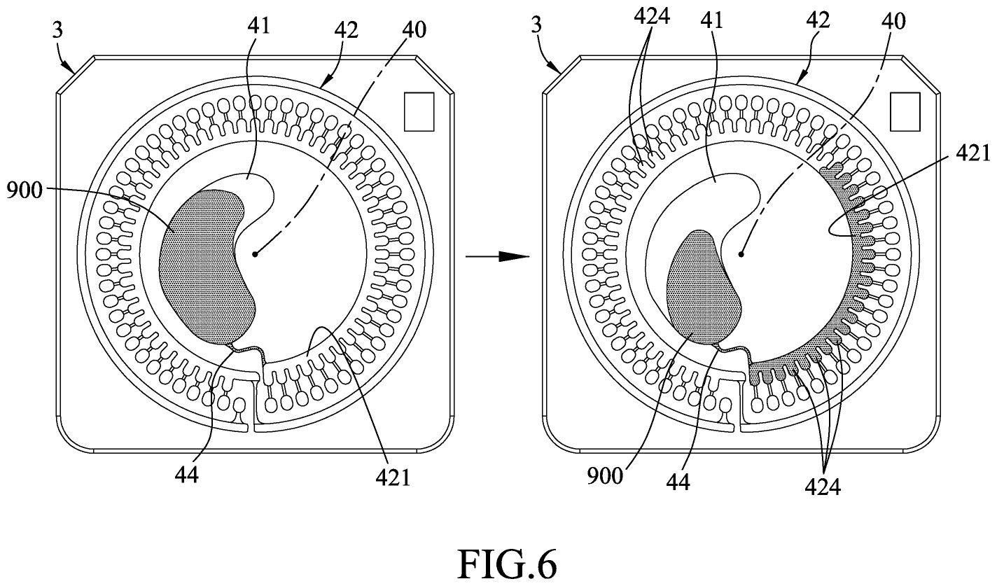

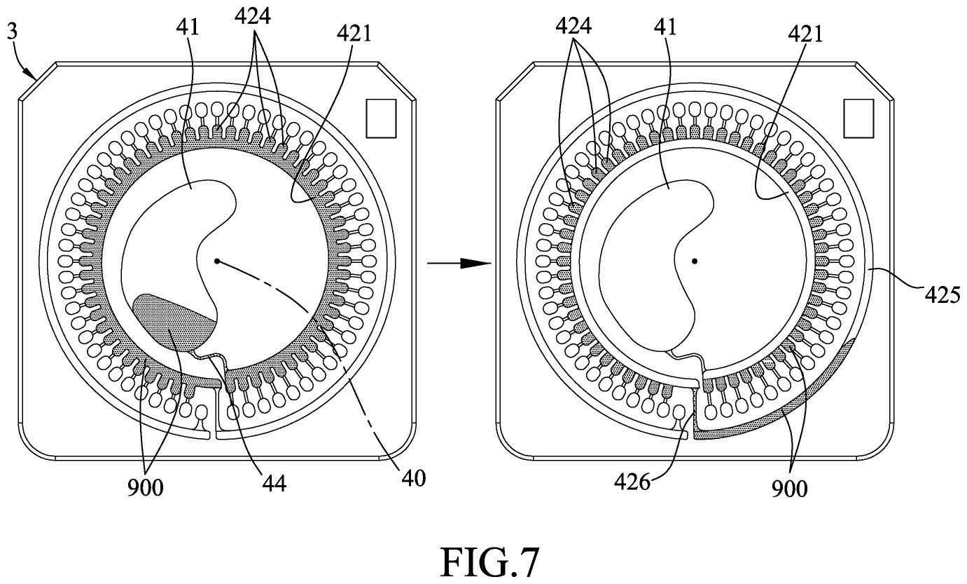

Refereeing to FIGS. 3, 6 and 7, when the reacting solution is injected into the sample reservoir 41, the reacting solution would be gathered at the second end 412 of the sample reservoir 41 due to the structures thereof (i.e., the depth of the sample reservoir 41 increases in the direction away from the rotation center 40 and increases from the first end 411 toward the second end 412, and the distance between the second end 412 and the rotation center 40 is greater than the distance between the first end 411 and the rotation center 40), thereby allowing the reacting solution to be distributed to the second end 412 by the centrifugal force (see the left side of FIG. 6). When the rotation speed exceeds a certain threshold value, such as 500 rpm, the centrifugal force is large enough to carry the reacting solution to pass through the first inlet channel 44 and enter the feeding groove portion 421 (see the right side of FIG. 6). Afterwards, the reacting solution would gradually flow from the first feeding end 422 toward the second feeding end 423 and gradually fill the metering groove portions 424 due to the involute extension of the feeding groove portion 421 and the centrifugal force. Since the amount of the centrifugal force is greater at the point farer away from the rotation center, the extension of the feeding groove portion 421 away from the rotation center 40 from the first feeding end 422 to the second feeding end 423 is effective in distributing the reacting solution in the feeding groove portion 421 with the help of the centrifugal force. After the reacting solution fills every metering groove portions 424 and is distributed to the second feeding end 423 of the feeding groove portion 421 (see the left side of FIG. 7), the remaining reacting solution would pass through the connecting groove portion 426 into the liquid storage groove portion 425 (see the right side of FIG. 7). The venting channel 427 and the venting groove portion 428 is used for discharging the gas in the microfluidic chip 3 to further facilitate the distribution of the reacting solution.

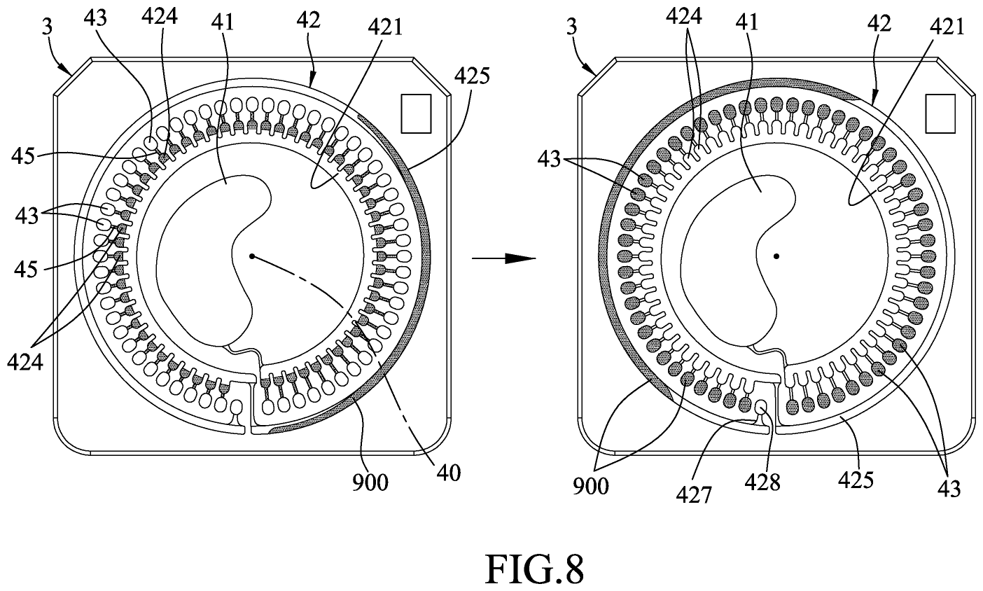

Referring to FIGS. 3 and 8, when the rotation speed further exceeds another threshold value, such as 3000 rpm, the centrifugal force corresponding to the 3000 rpm rotation would drive the reacting solution in the metering groove portions 424 to respectively pass through the second inlet channels 45 and into the reaction chambers 43. Then, the reagents 6 in the reaction chambers 43 would react with the reacting solution.

With the structural arrangement of the grooves of the microfluidic chip 3 and the above-disclosed two-step distribution, the reacting solution in the sample reservoir 41 having a volume of 2 to 3 mL can be precisely distributed into multiple reaction chambers 43 at microliter level. With the meandering structural design of the feeding groove portion 421 of the liquid groove 42 and the liquid storage groove portion 425 and the connection through the first and second inlet channels 44, 45 and the connecting groove portion 426, the reacting solution can be evenly distributed to the reaction chambers 43 of the microfluidic chip 3.

Moreover, with the chip main body 4 being made of hydrophobic material, and the first inlet channel 44 and the second inlet channels 45 being shallower than the groove portions connected thereto, the reacting solution is prevented from entering adjacent grooves without action of the centrifugal force and is prevented from backflowing from the reaction chambers 43, which may contaminate the reacting solution or affect the test results.

It should be noted that the feeding groove portion 421 may not extend along the path shaped as the involute of the circle, as long as the feeding groove portion 421 and the liquid storage groove portion 425 extend around the rotation center 40 to allow the centrifugal force to be applied to distribute the reacting solution.

The venting hole 52 of the sealing membrane 5 provides an outlet for the gas in the grooves, allowing the reacting solution to be smoothly distributed in the microfluidic chip 3. Alternatively, the sealing membrane 5 may be made of a waterproof and breathable single-layered membrane or multiple-layered composite membrane, made of polytetrafluoroethylene (PTFE), polyurethane (PU), thermoplastic polyurethane (TPU), biaxially oriented polypropylene (BOPP), etc. The waterproof and breathable property allows air to exit the microfluidic chip 3 while preventing the reacting solution from leaking out.

Referring FIGS. 1, 9 and 10, the microscopic image system 7 includes machine case assembly 71, an image capture device 72, a holding platform assembly 73, a code reader 74 and a control module 75.

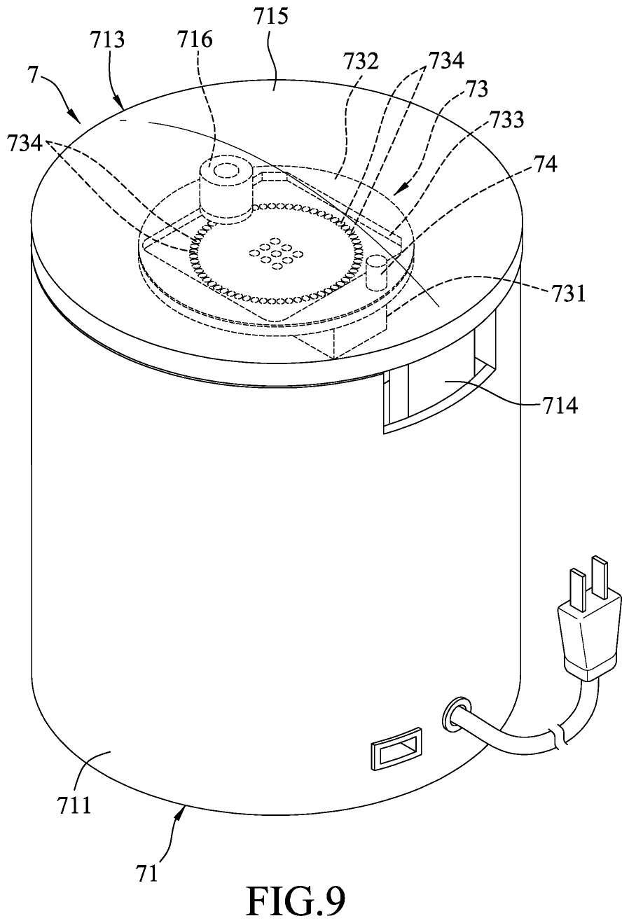

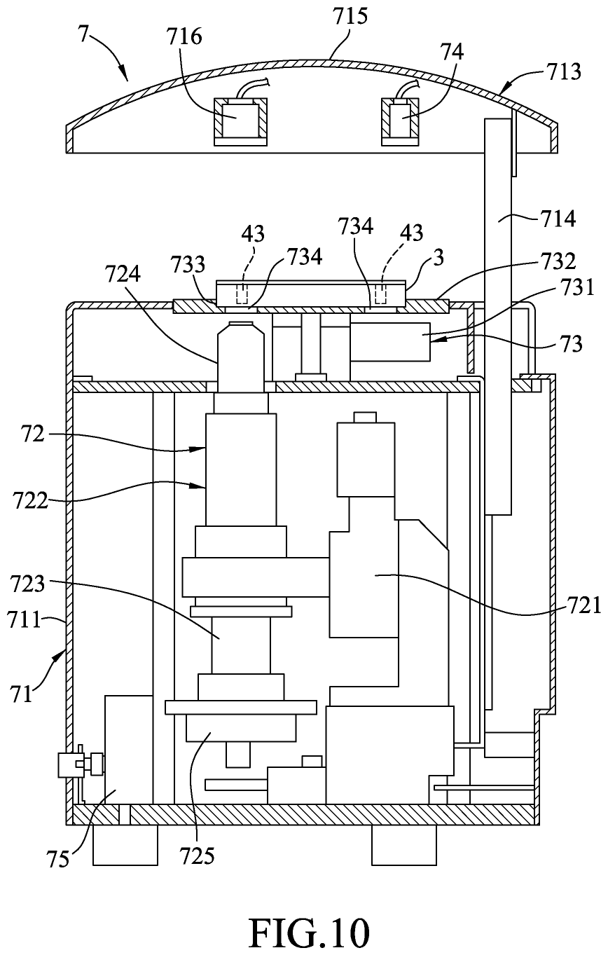

The machine case assembly 71 includes a machine case 711 and a light source unit 713. The light source unit 713 includes a lifting frame 714 that is mounted to and movable vertically relative to the machine case 711, a cover 715 that is fixed to the lifting frame 714 and that is disposed above the machine case 711, and alight emitting member 716 that is mounted to the cover 715 and that is operable to emit light downwardly into the machine case 711. The cover 715 is co-movable with the lifting frame 714 to cover the top end of the machine case 711 (see FIG. 9), and to uncover the top end of the machine case 711 (see FIGS. 1 and 10).

The image capture device 72 is mounted to the machine case 711, and includes a focus adjusting module 721 that is fixed within the machine case 711 and a microscopic image module 722 that is mounted to the focus adjusting module 721 and that is located within the lighting area of the light emitting member 716 of the light source unit 713. The focus adjusting module 721 can be controlled by the control module 75 to vertically move the microscopic image module 722 relative to the holding platform assembly 73.

The microscopic image module 722 includes a lens barrel 723, an objective lens 724 and a photodetector 725. The objective lens 724 is disposed within the lighting area of the light source unit 713 and is adapted to capture image. The lens barrel 723 extends vertically and is connected to a lower end of the objective lens 724. The photodetector 725 is connected to a lower end of the lens barrel 723 and is adapted for capturing image through the objective lens 724. In this embodiment, the photodetector 725 includes a CMOS sensor, which can sense the optical image from the objective lens 724 via the lens barrel 723 to obtain image data. The lens barrel 723 is used for a suitable optical distance between the objective lens 724 and the photodetector 725, and the length of the lens barrel 723 should correspond to the tube length distance of the objective lens 724, allowing the objective lens 724 to capture a clear image. In certain embodiments, the objective lens 724 may have a magnification of 10×, 20×, 40×, 100×, etc. The objective lens 724, the photodetector 725 and the lens barrel 723 cooperate with each other to provide certain image magnification, such as 100×, 200×, 300×, 500×, etc.

The holding platform assembly 73 includes a driving unit 731 that is mounted to the machine case 711, and a holding platform 732 that is mounted to the driving unit 731 and that is disposed above the objective lens 724. The top surface of the holding platform 732 is indented and formed with a positioning groove 733 that is for the microfluidic chip 3 to be fixed therein, and has a plurality of inspection through holes 734 that are formed therethrough and that are in spatial communication with the positioning groove 733. The inspection through holes 734 are arranged about an axis of rotation of the holding platform 732, are spaced apart from each other, and are respectively located below the reaction chambers 43 of the microfluidic chip 3. The driving unit 731 can be controlled by the control module 75 to drive horizontal rotation of the holding platform 732 and the microfluidic chip 3 relative to the machine case 711, allowing one of the inspection through holes 734 to be moved to the optical image path of the objective lens 724 and the microscopic image module 722 to capture images of the reaction chambers 43.

The code reader 74 is mounted to the cover 715 and is in signal connection with the control module 75. The code reader 74 can be controlled by the control module 75 to scan downwardly the identification code 30 of the microfluidic chip 3 to obtain an identification data.

Referring to FIGS. 1, 10 and 11, the control module 75 is mounted to the machine case 711, is in signal connection with the light emitting member 716, the focus adjusting module 721, the photodetector 725, the driving unit 731 and the code reader 74, and is adapted to be in signal connection with the control system 800. The control module 75 includes a focus control unit 751, a chip moving unit 752, a code reader control unit 753, alight control unit 754 and an output control unit 755.

The focus control unit 751 is drivable by a focus signal generated by the control system 800 to control the focus adjusting module 721 to vertically move the microscopic image module 722, that is, to adjust the distance between the microscopic image module 722 and the microfluidic chip 3 to achieve the purpose of focusing. The chip moving unit 752 is drivable by a moving signal generated by the control system 800 to control the driving unit 731 to move the holding platform 732, such that the holding platform 732 moves the microfluidic chip 3 to rotate horizontally so as to move a certain reaction chamber 43 to be position in the optical path of the objective lens 724. The code reader control unit 753 is drivable by a reading signal generated by the control system 800 to control the code reader 74 to read an identification code to thereby obtain an identification data. The output control unit 755 combines the image data and the identification data, and transmits conjointly to the control system 800.

After the reagents 6 in the reaction chambers 43 react with the reacting solution (e.g., serum or testing bacteria sample), the microfluidic chip is placed in the positioning groove 733 of the holding platform 732. Then, the control system 800 is operated to control the microscopic image system 7, such as driving the driving unit 731 to move the holding platform 732 so as to rotate the microfluidic chip 3 to position a certain reaction chamber 43 in the optical path of the objective lens 724, thereby controlling the focus adjusting module 721 to move the microscopic image module 722 vertically relative to the microfluidic chip 3 to achieve focus and to capture image. The control module 75 of the microscopic image system 7 transmits, through the output control unit 755, the identification data and the image data of the microfluidic chip 3 to the control system 800 for image analysis.

Referring to FIGS. 1 and 9, when the microscopic image system 7 is shut down and not being used, the lifting frame 714 is driven to retract back to the machine case 711 to move the cover 715 to cover the top end of the machine case 711 so as to cover the inspection through holes 734 of the holding platform 732, preventing dust from contaminating the optical elements.

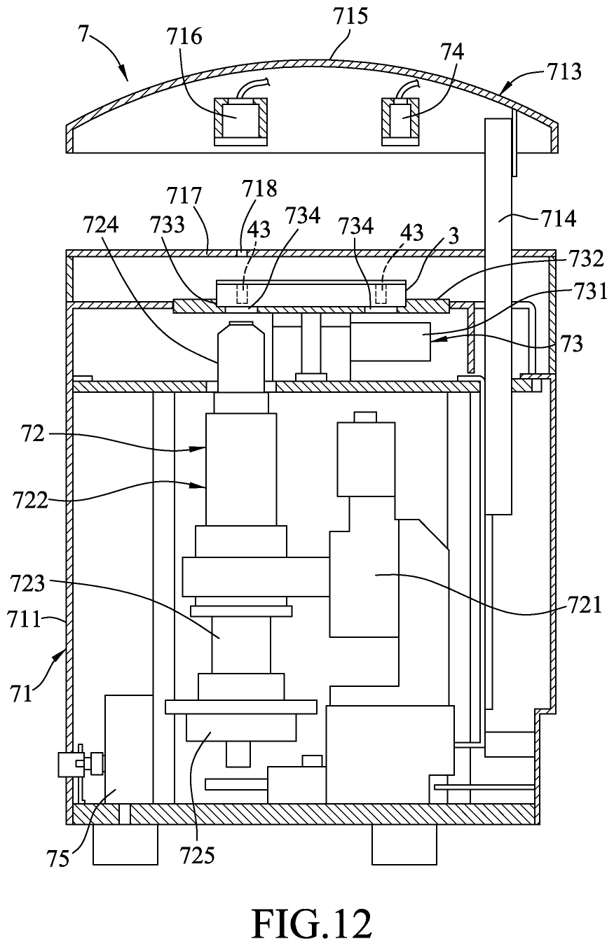

Referring to FIGS. 10 and 12, alternatively, the machine case assembly 71 may further includes a light shielding plate 717 that is mounted to the top end of the machine case 711 and that is disposed between the holding platform 732 and the light emitting member 716. The light shielding plate 717 is formed with a light through hole 718 that is located in an optical path of the objective lens 724 and that allows the light emitted by the light emitting member 716 to pass therethrough and to be transmitted to the objective lens 724, thereby allowing the microscopic image system 7 to be used for optical inspection of fluorescent samples in the microfluidic chip 3.

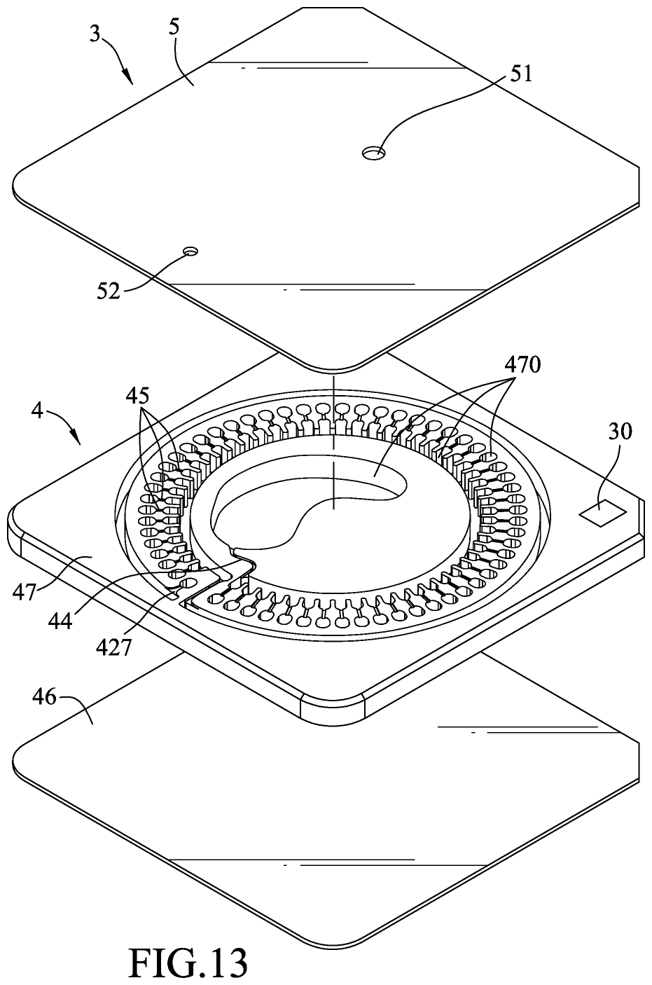

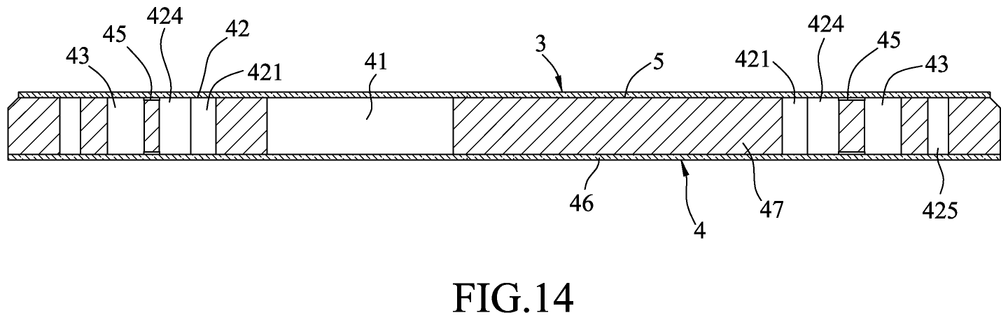

Referring to FIGS. 13 and 14, an alternative microfluidic chip 3 is provided.

In this alternative, the chip main body 4 of the microfluidic chip 3 is laminated structured, and has a bottom layer 46 and a main body layer 47 disposed on and connected to the bottom layer 46. The main body layer 47 is indented to form the first inlet channel 44, the second inlet channels 45 and the venting channel 427, and has a through hole 470 that is formed therethrough and that cooperates with the bottom layer 46 to define the sample reservoir 41, the liquid groove 42 and the reaction chambers 43. The sealing membrane 5 is connected to a top surface of the main body layer 47. The reagents 6 may be fixed to the top surface of the bottom layer 46 or the side walls of the main body layer 47 defining the reaction chambers 43.

In view of the above, the abovementioned grooves of the microfluidic chip 3 allow the reacting solution to be preciously and rapidly distributed to the reaction chambers 43, such that the reagents 6 disposed in the reaction chambers 43 can be used for reacting with the reacting solution to perform single or multiple testing. The hydrophobic property of the chip main body 4 and the structure of the second inlet channels 45 prevent the solution in the reaction chambers 43 from backflowing and cross contamination. Moreover, the involute extension of the feeding groove portion 421 improves the distribution of the reacting solution in the reaction chambers 43.

Moreover, the horizontal rotation and vertical focusing of the microscopic image system 7 allow rapid and precise image capture of the reaction chambers 43 of the microfluidic chip 3. The rotation design produces less noise and is more flexible and easy to miniaturize compared to conventional X-Y positioning platform. The cover 715 of the light source unit 713 and the light emitting member 716 can reduce the influence of ambient light. The code reader 74 allows the identification code information of the microfluidic chip 3 and the test results to be linked, reducing the risk of human error.

In the description above, for the purposes of explanation, numerous specific details have been set forth in order to provide a thorough understanding of the embodiment. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiment, it is understood that this disclosure is not limited to the disclosed embodiment but is intended to cover various arrangements included within the spirit and scope of the broadest interpretation so as to encompass all such modifications and equivalent arrangements.

What is claimed is:

1. A microfluidic chip comprising:
a chip main body having
a rotation center,
a sample reservoir,
a liquid groove having
a feeding groove portion that extends around said rotation center and said sample reservoir, and
a plurality of metering groove portions that are disposed around said feeding groove portion, that extend from said feeding groove portion in a direction away from said rotation center, and that are spaced apart from each other along the length of said feeding groove portion,
a plurality of reaction chambers that are disposed around said metering groove portions,
a first inlet channel that is in fluid communication with and disposed between said sample reservoir and said feeding groove portion, and
a plurality of second inlet channels, each of which is in fluid communication with and disposed between a respective one of said metering groove portions and a respective one of said reaction chambers; and
a sealing membrane connected to said chip main body, covering said sample reservoir, said liquid groove, said reaction chambers, said first inlet channel, and said second inlet channels so as to seal top ends thereof, and having a sample injection hole that is formed therethrough and that is in fluid communication with said sample reservoir,
wherein the depth of said first inlet channel is smaller than those of said sample reservoir and said feeding groove portion, and
wherein the depth of each of said second inlet channels is smaller than the depth of the respective metering groove portion, the depth of the respective reaction chamber, and the depth of said first inlet channel.

2. The microfluidic chip as claimed in claim 1, wherein:
said feeding groove portion of said liquid groove has a first feeding end and a second feeding end opposite to said first feeding end;
said first inlet channel is in fluid communication with and disposed between said sample reservoir and said first feeding end of said feeding groove portion; and
said feeding groove portion extends gradually away from said rotation center from said first feeding end to said second feeding end.

3. The microfluidic chip as claimed in claim 2, wherein each of said second inlet channels extends from the respective metering groove portion to the respective reaction chamber in a manner that the extension length thereof decreases from one corresponding to said first feeding end of said feeding groove portion toward one corresponding to said second feeding end of said feeding groove portion.

4. The microfluidic chip as claimed in claim 1, wherein said liquid groove further has a liquid storage groove portion that extends around said feeding groove portion and that has a first end and a second end opposite to said first end, and a connecting groove portion that is in fluid communication with and disposed between said feeding groove portion and said first end of said liquid storage groove portion and that extends radially and outwardly from said feeding groove portion relative to said rotation center.

5. The microfluidic chip as claimed in claim 4, wherein:
said feeding groove portion extends along a path shaped as an involute of a circle;
said metering groove portions surround said feeding groove portion;
said reaction chambers surround said metering groove portions; and
said liquid storage groove portion extends along a circle and surrounds said reaction chambers.

6. The microfluidic chip as claimed in claim 4, wherein:
said liquid groove further has a venting channel that extends from said second end of said liquid storage groove portion toward said rotation center, and a venting groove portion that communicates with an end of said venting channel distal from said liquid storage groove portion;
the depth of said venting channel is smaller than those of said liquid storage groove portion and said venting groove portion; and
said sealing membrane is further formed with a venting hole that communicates with said venting groove portion.

7. The microfluidic chip as claimed in claim 1, wherein:
said sample reservoir extends around said rotation center, and has a first end and a second end that are respectively located at two sides of said rotation center;
said first end of said sample reservoir is in fluid communication with said sample injection hole of said sealing membrane;
said second end of said sample reservoir is in fluid communication with said first inlet channel; and
the distance between said second end of said sample reservoir and said rotation center is greater than the distance between said first end of said sample reservoir and said rotation center.

8. The microfluidic chip as claimed in claim 7, wherein the depth of said sample reservoir increases in a direction away from said rotation center and increases from said first end of said sample reservoir toward said second end of said sample reservoir.

9. The microfluidic chip as claimed in claim 1, wherein said sealing membrane is one of an airtight membrane and a waterproof-breathable membrane.

10. The microfluidic chip as claimed in claim 1, wherein said chip main body is made of hydrophobic material.

11. The microfluidic chip as claimed in claim 1, wherein:
said chip main body has a bottom layer and a main body layer disposed on said bottom layer; and
said main body layer is indented to form said first inlet channel and said second inlet channels, and has a through hole that is formed therethrough and that cooperates with said bottom layer to define said sample reservoir, said liquid groove and said reaction chambers.

12. A microscopic image system comprising:
a machine case assembly including a machine case, and a light source unit that is mounted to said machine case and that is operable to emit light downwardly;
an image capture device mounted to said machine case, and including a focus adjusting module and a microscopic image module that is mounted to said focus adjusting module, said microscopic image module being drivable by said focus adjusting module to move vertically, said microscopic image module including an objective lens that is within the lighting area of said light source unit and that is adapted to capture image, a lens barrel that extends vertically and that is connected to a lower end of said objective lens and a photodetector that is connected to a lower end of said lens barrel and that is adapted for capturing image through said objective lens; and
a holding platform assembly including a driving unit that is mounted to said machine case, and a holding platform that is mounted to said driving unit and that is disposed above said objective lens, said holding platform having a plurality of inspection through holes formed therethrough and being drivable by said driving unit to move horizontally such that a selected one of said inspection through holes is positioned above said objective lens.

13. The microscopic image system as claimed in claim 12, wherein said driving unit is operable to drive said holding platform to rotate horizontally, said inspection through holes of said holding platform being arranged about an axis of rotation of said holding platform and being spaced apart from each other.

14. The microscopic image system as claimed in claim 12, wherein said light source unit includes a lifting frame that is mounted to and movable vertically relative to said machine case, a cover that is fixed to said lifting frame and that is disposed above said machine case, and a light emitting member that is mounted to said cover and that is operable to emit light downwardly into said machine case.

15. The microscopic image system as claimed in claim 14, wherein:
said machine case assembly further includes a light shielding plate that is mounted to a top end of said machine case and that is disposed between said holding platform and said light emitting member; and
said light shielding plate is formed with a light through hole that is located in an optical path of said objective lens and that allows the light emitted by said light emitting member to pass therethrough to thereby being transmitted to said objective lens.

16. The microscopic image system as claimed in claim 12, wherein:
said microscopic image system is adapted to be in signal connection with a control system;
said microscopic image system further includes a control module that is mounted to said machine case, that is in signal connection with said focus adjusting module and said driving unit and that is adapted to be in signal connection with the control system;
said control module includes
a focus control unit that is drivable by a focus signal generated by the control system to control said focus adjusting module to vertically move said microscopic image module,
a chip moving unit that is drivable by a moving signal generated by the control system to control said driving unit to move said holding platform, such that another one of said inspection through holes is located in the optical path of said objective lens, and
an output control unit that is operable to transmit an image data detected by said photodetector to the control system.

17. The microscopic image system as claimed in claim 16, further comprising a code reader that is in signal connection with said control module, said control module further including a code reader control unit that is drivable by a reading signal generated by the control system to control said code reader to read an identification code to thereby obtain an identification data, said output control unit combining the image data and the identification data and transmitting the same to the control system.

18. The microscopic image system as claimed in claim 16, wherein said control module further includes a light control unit that is drivable by a light adjusting signal generated by the control system to control the brightness of said light source unit.
